(19) United States
(12) Patent Application Publication
(10) Pub. No.: US 2012/0300375 A1
(43) Pub. Date: Nov. 29, 2012

(54) CLAMSHELL ELECTRONIC DEVICE, SWITCHING MODULE AND SWITCHING METHOD

(75) Inventor: Ta-Wei HSU, New Taipei City (TW)

(73) Assignee: WISTRON CORP., New Taipei City (TW)

(21) Appl. No.: 13/469,834

(22) Filed: May 11, 2012

(30) Foreign Application Priority Data
May 27, 2011 (TW) 100118630

(51) Int. Cl. H05K 5/00; H01H 35/02

(52) U.S. Cl. 361/679.01; 307/119

(57) ABSTRACT

The present disclosure discloses a clamshell electronic device including an upper cap, a bottom lid, a first battery, a second battery, a sensing device and a control device. When the clamshell electronic device is under a working state, the first battery provides a system operating voltage to the clamshell electronic device, and the first battery provides a system operating voltage to the clamshell electronic device. When the clamshell electronic device is under a first state, the second battery provides a booting voltage to the clamshell electronic device, and the sensing device produces a first trigger signal according to the upper cap flipped up from the bottom lid. The control device is coupled to the sensing device, and enables the system operating voltage to be provided to the clamshell electronic device according to the first trigger signal, such that the clamshell electronic device enters the working state from the first state.

### CROSS REFERENCE TO RELATED APPLICATIONS

This application claims priority of Taiwan Patent Application No. 100118630, filed on May 27, 2011, the entirety of which is incorporated by reference herein.

### BACKGROUND OF THE DISCLOSURE

1. Field of the Disclosure

The present disclosure relates to a clamshell electronic device, and in particular relates to a clamshell electronic device with a switching module to turn on the power of the clamshell electronic device when the upper cap has been flipped up from the bottom lid.

2. Description of the Related Art

Current mobile devices, such as laptops, mobile phones, and translators, typically have an upper cap and a bottom lid. The clamshell electronic device usually protects keys and a screen by covering them between an upper cap and a bottom lid. When personal computer users use the clamshell electronic device, they must first open the upper cap to press the power button.

In view of this, the purpose of the present disclosure provides a more convenient way to accelerate the speed of booting a clamshell electronic device.

### BRIEF SUMMARY OF THE DISCLOSURE

A detailed description is given in the following embodiments with reference to the accompanying drawings.

The present disclosure discloses a clamshell electronic device including an upper cap, a bottom lid, a first battery, a second battery, a sensing device and a control device. When the clamshell electronic device is under a working state, the first battery provides a system operating voltage to the clamshell electronic device. During the working state, the operating system and application program of the clamshell electronic device is normally executed. When the clamshell electronic device is under a first state, the second battery provides a booting voltage to the clamshell electronic device. The sensing device has a first pin coupled to the booting voltage and a second pin coupled to the ground. When the clamshell electronic device is under a first state, the sensing device is used to produce a first trigger signal according to the upper cap flipped up from the bottom lid. The control device has a first pin coupled to a third pin of the sensing device, and enables the system operating voltage to be provided to the clamshell electronic device according to the first trigger signal, such that the clamshell electronic device enters the working state from the first state.

Additionally, the present disclosure further discloses a switching module. The switching module is configured on a clamshell electronic device and comprises a sensing device and a control device. The source of the power of the sensing device is powered by a booting voltage, and the sensing device is used to detect whether the upper cap of the clamshell electronic device has been flipped up from the bottom lid of the clamshell electronic device when the clamshell electronic device is under a first state. When the upper cap of the clamshell electronic device has been flipped up from the bottom lid of the clamshell electronic device, the sensing device produces a first trigger signal. The control device turns on a system operating voltage to provide the power of the clamshell electronic device according to the first trigger signal, such that the clamshell electronic device is converted to a working state from the first state. The booting voltage is provided by a battery. The battery applies power to the clamshell electronic device when the clamshell electronic device is under the first state.

Furthermore, the present disclosure discloses a switching method applied to a clamshell electronic device. The switching method comprises: detecting whether the upper cap of a clamshell electronic device has been flipped up from the bottom lid of the clamshell electronic device by a sensing device when the clamshell electronic device is under a first state; producing a trigger signal when the upper cap of the clamshell electronic device has been flipped up from the bottom lid; and forcing a system operating voltage to be turned on and provided to the clamshell electronic device according to the trigger signal, such that the clamshell electronic device enters into a working state from the first state.

### BRIEF DESCRIPTION OF THE DRAWINGS

The present disclosure can be more fully understood by reading the subsequent detailed description and examples with references made to the accompanying drawings, wherein:

FIG. 1 is a schematic diagram illustrating an embodiment of a clamshell electronic device of the present disclosure;

FIG. 2 is a schematic diagram illustrating an embodiment of a switching module of the present disclosure;

FIG. 3 is a schematic diagram illustrating another embodiment of the switching module of the present disclosure;

FIG. 4 is a schematic diagram illustrating another embodiment of the switching module of the present disclosure; and

FIG. 5 is a flowchart of a switching method according to an embodiment of the present disclosure.

### DETAILED DESCRIPTION OF THE DISCLOSURE

The following description is of the best-contemplated mode of carrying out the disclosure. This description is made for the purpose of illustrating the general principles of the disclosure and should not be taken in a limiting sense. The scope of the disclosure is best determined by reference to the appended claims.

For conventional computer systems (e.g. computer systems with Microsoft Windows operating system), power management for reducing power consumption can be achieved by using the standby states as defined by the “Advanced Configuration and Power Interface (ACPI)”. There are six states S0 to S5 defined by the ACPI. State S0 indicates that the computer system is at working state. In the standby state S1, the CPU in the computer system is not working, and in the standby state S2, the CPU in the computer system shutdowns. State S3 is a standby state with a short resuming time (e.g. 5 seconds or shorter), for a computer system to recover to the working state (e.g. state S0). The standby state S4 is regarded as a “suspend to disk” state, wherein the computer system has low power consumption and long resuming time (e.g. 20 seconds or longer). The aforementioned standby states S1 to S4 save power at different levels, and state S5 is a shutdown state. During the state S5, the computer's power consumption approaches close to zero, but some components remain powered so the computer can be woken up by the keyboard, clock, modem (modem resume), LAN (LAN resume), or USB device. It should be noted that the working states, standby states, the power saving states and the shutdown state in the present disclosure is defined by the ACPI, but it is not limited thereto. The first state of the present disclosure comprises the disclosed standby states and shutdown state.

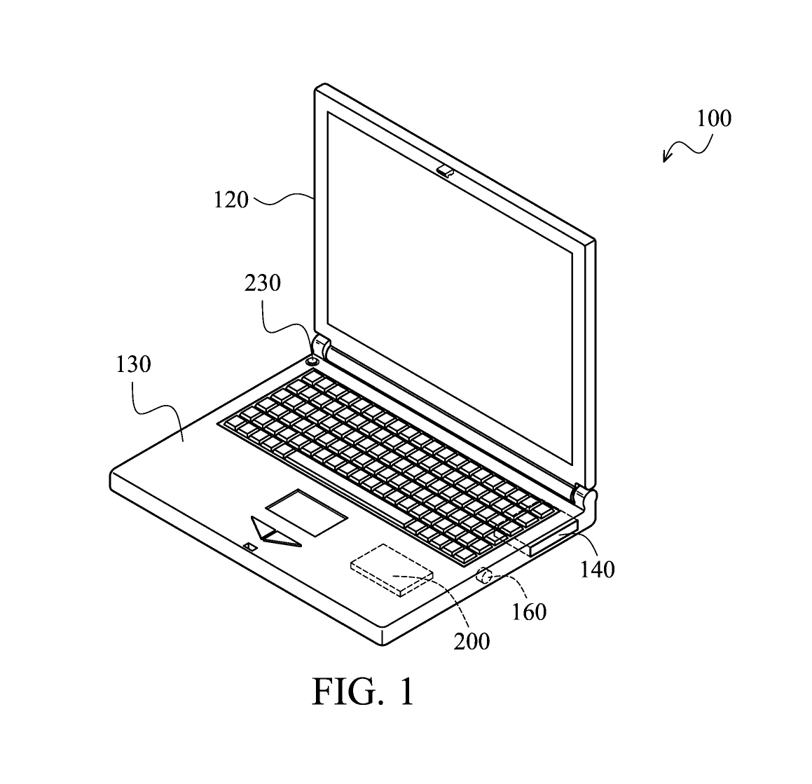

FIG. 1 is a schematic diagram illustrating an embodiment of a clamshell electronic device 100 of the present disclosure, wherein the clamshell electronic device 100 includes an upper cap 120, a bottom lid 130, a first battery 140, a second battery 160, and a switching module 200. When the clamshell electronic device 100 is under a working state, the first battery 140 provides the system operating voltage to the clamshell electronic device 100. When the clamshell electronic device 100 is under the first state, the first battery 140 does not provide the system operating voltage to the clamshell electronic device 100, but the second battery 160 provides a booting voltage to the clamshell electronic device 100. When users turn on the clamshell electronic device 100 by flipping up the upper cap 120 or pressing the switch 230, the second battery 160 provides the booting voltage to the clamshell electronic device 100 to turn on the clamshell electronic device 100. The switching module 200 detects whether the upper cap 120 of the clamshell electronic device 100 has been flipped up from or closed down to the bottom lid 130 of the clamshell electronic device 100. When the upper cap 120 of the clamshell electronic device 100 has been flipped up from the bottom lid 130 of the clamshell electronic device 100, the switching module 200 enables the system operating voltage to be provided to the clamshell electronic device 100, such that the clamshell electronic device 100 enters the working state from the first state, wherein the first state is the standby state or the shutdown state. In the present embodiment, the clamshell electronic device 100 is a notebook, but it is not limited thereto. A notebook is one of the embodiments of the present disclosure, and the clamshell electronic device 100 can be any electronic device having an upper cap 120 and a bottom lid 130, such as Clamshell phones, slide mobile phones, netbooks, etc. The second battery 160 can be a mercury battery or a large capacitor (i.e., the real time clock (RTC) of the common computer). Generally speaking, the storage capacity of the second battery 160 is less than the first battery 140. In the embodiment, the switching module 200 is set in the bottom lid 130 of the clamshell electronic device 100, but in the another embodiment the switching module 200 can be set in the upper cap 120 of the clamshell electronic device 100. In addition, the states of the clamshell electronic device 100 can also be controlled to enter into the working state from the first state by a switch 230 instead of the switching module 200.

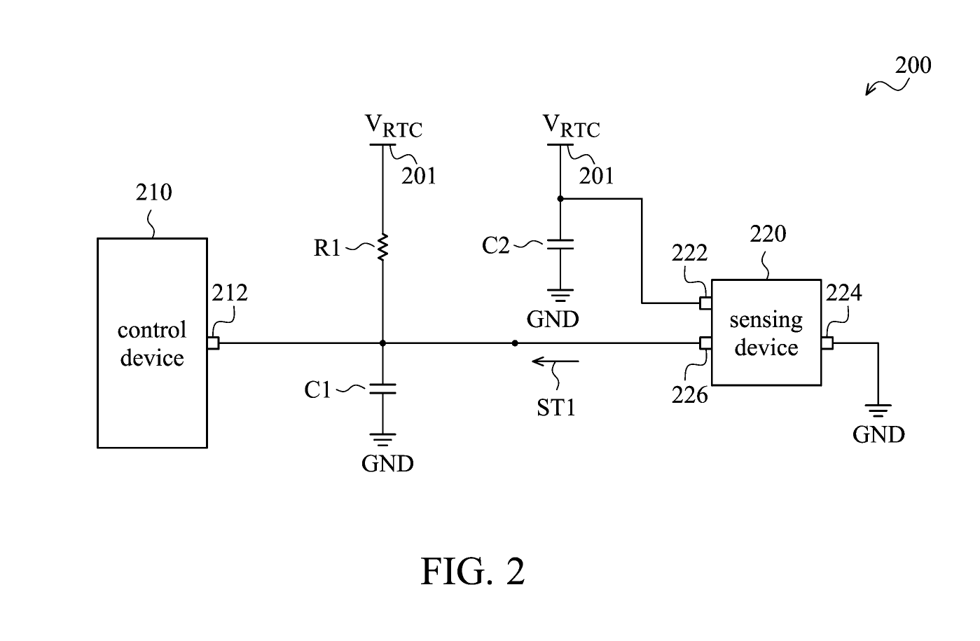

FIG. 2 is a schematic diagram illustrating an embodiment of a switching module 200 of the disclosure. As shown in FIG. 2, the switching module 200 includes a control device 210, a sensing device 220, a resistor R1, a capacitor C1, and a capacitor C2. In the embodiment, the control device 210 is a keyboard controller or embed controller, but the present disclosure is not limited thereto. The sensing device 220 detects whether the status of the upper cap 120 and the bottom lid 130 of the clamshell electronic device 100 has changed, for example, the sensing device 220 detects whether the upper cap 120 is opened or closed (flipped up/down). The sensing device 220 includes a first pin 222, a second pin 224, and a third pin 226. The first pin 222 of the sensing device 220 is coupled to a booting voltage V_{RTC} of a power line 201, wherein the booting voltage V_{RTC} provides the power of the sensing device 220. The second pin 224 of the sensing device 220 is coupled to the ground GND, and arranged to provide a voltage lower than the booting voltage V_{RTC} to the sensing device 220. The third pin 226 of the sensing device 220 is coupled to a first pin 212 of the control device 210, and used for sending a trigger signal ST1 to the control device 210. The resistor R1 has a first terminal coupled to the booting voltage V_{RTC} of power line 201 and a second terminal coupled to a third pin 226 of the sensing device 220. The resistor R1 is arranged to pull high the voltage level on the third pin 226 of the sensing device 220. The capacitor C1 has a first terminal coupled to the third pin 226 of the sensing device 220 and a second terminal coupled to the ground GND. The capacitor C1 pre-charges the voltage on the first pin 212 of control device 210. The capacitor C2 has a first terminal coupled to the first pin 222 of the sensing device 220 and a second terminal coupled to the ground GND. The capacitor C2 stabilizes the voltage and current on the first pin 222 of the sensing device 220. It should be noted that the sensing device 220 of the present embodiment is a hall sensor, and the hall sensor detects whether the upper cap 120 of the clamshell electronic device 100 has been flipped up from the bottom lid 130 of the clamshell electronic device 100 by the electromagnetic change, but the present disclosure is not limited thereto. In some embodiments, the sensing device 220 can be other micro-switch.

When the clamshell electronic device 100 is under the first state (i.e. the states S3, S4 or S5 of the ACPI standard), the first battery 140 does not provide the system operating voltage to the clamshell electronic device 100, but the second battery 160 provides the booting voltage V_{RTC} to the power line 201. At this time, although the clamshell electronic device 100 is under the first state, because the second battery 160 is providing the booting voltage V_{RTC} to the sensing device 220 and the control device 210, the third pin 226 of the sensing device 220 and the first pin 212 of the control device 210 can be maintained at a high voltage level by the power line 201. When the user opens the upper cap 120 of the clamshell electronic device 100, the sensing device 220 detects that the upper cap 120 of the clamshell electronic device 100 has been flipped up from the bottom lid 130 of the clamshell electronic device 100. Accordingly, the sensing device 220 pulls the third pin 226 to ground from the high voltage level. At this time, the first pin 212 of the control device 210 is pulled down to a low voltage level and then back to the high voltage level subsequently. Namely, the sensing device 220 produces a trigger signal ST1 (low-to-high) and sends the trigger signal ST1 to the first pin 212 of the control device 210. After the control device 210 receives the trigger signal ST1, the control device 210 forces the system operating voltage to be provided to the clamshell electronic device 100 according to the trigger signal ST1 and the clamshell electronic device 100 to enter into the working state from the first state (i.e. enter into the state S0 from state S5 of the ACPI standard). For example, the control device 210 can send a signal to a starter circuit of the clamshell electronic device 100 (not shown), wherein the starter circuit enables the system operating voltage of the first battery 140 or an external voltage source to be provided to the clamshell electronic device 100 to execute the related booting process.

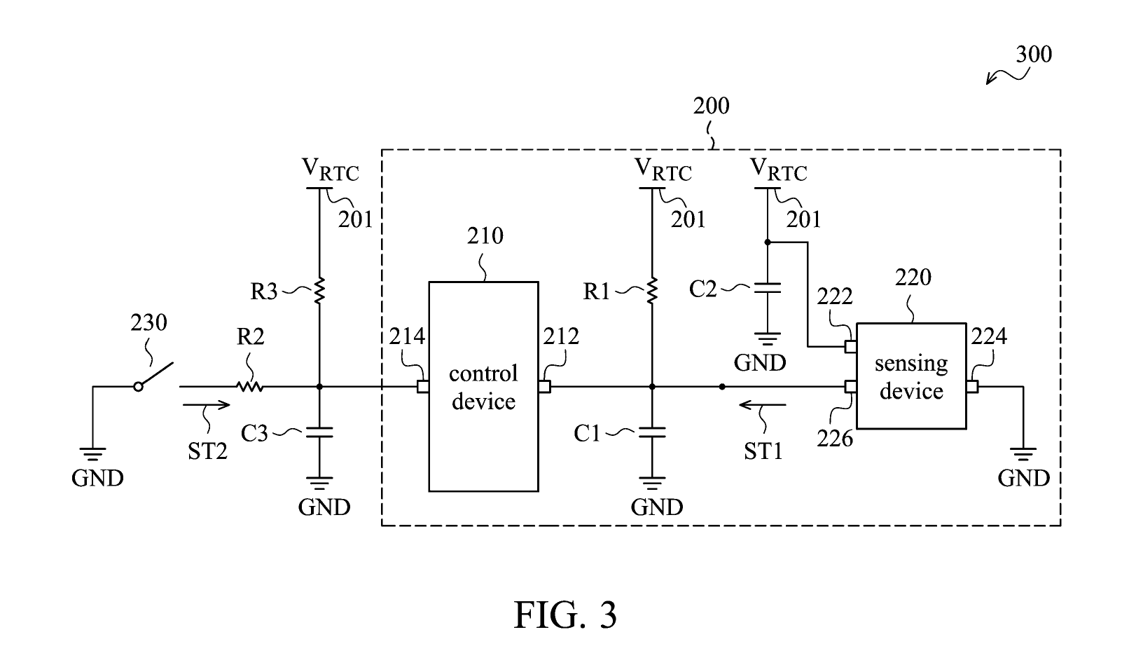

FIG. 3 is a schematic diagram illustrating another embodiment of the switching module of the present disclosure. The switching module 300 can boot the clamshell electronic device 100 by a switch 230 in addition to the trigger signal ST1. Compared with the switching module 200 of FIG. 2 with the switching module 300, the switching module 300 further comprises a switch 230, a resistor R2, a resistor R3 and a capacitor C3. For simplification, the connections and operations of other devices of the switching module 300 will not be described in detail here, as reference may be made to the description of FIG. 2. The switch 230 has a first terminal coupled to the ground GND and a second terminal coupled to the second pin 214 of the control device 210. The switch 230 produces a trigger signal ST2 to the control device 210, when the switch 230 is pressed. The resistor R2 has a first terminal coupled to the second terminal of the switch 230 and a second terminal coupled to the second pin 214 of the control device 210. The resistor R3 has a first terminal coupled to the booting voltage V_{RTC} of the power line 201 and a second terminal coupled to the second pin 214 of the control device 210. The resistor R3 pulls high the output voltage at the second terminal of the switch 230. The capacitor C3 has a first terminal coupled to the second pin 214 of the control device 210 and a second terminal coupled to the ground GND. The capacitor C3 pre-charges the voltage at the second pin 214 of the control device 210.

When the clamshell electronic device 100 is under the first state (i.e. the states S3, S4 or S5 of the ACPI standard), the first battery 140 does not provide the system operating voltage to the clamshell electronic device 100, but provides the booting voltage V_{RTC} to the second battery 160 by a power line 201. In the meanwhile, the second terminal of switch 230 and the second pin 214 of the control device 210 is maintained at a high voltage level. When the user presses the switch 230, the switch 230 produces a trigger signal ST2 to the second pin 214 of the control device 210. After the control device 210 receives the trigger signal ST2, the control device 210 forces the system operating voltage to be provided to the clamshell electronic device 100 according to the trigger signal ST2 and the clamshell electronic device 100 enters into the working state from the first state, such as entering into the state S0 from state S5 of the ACPI standard, but the present disclosure is not limited thereto.

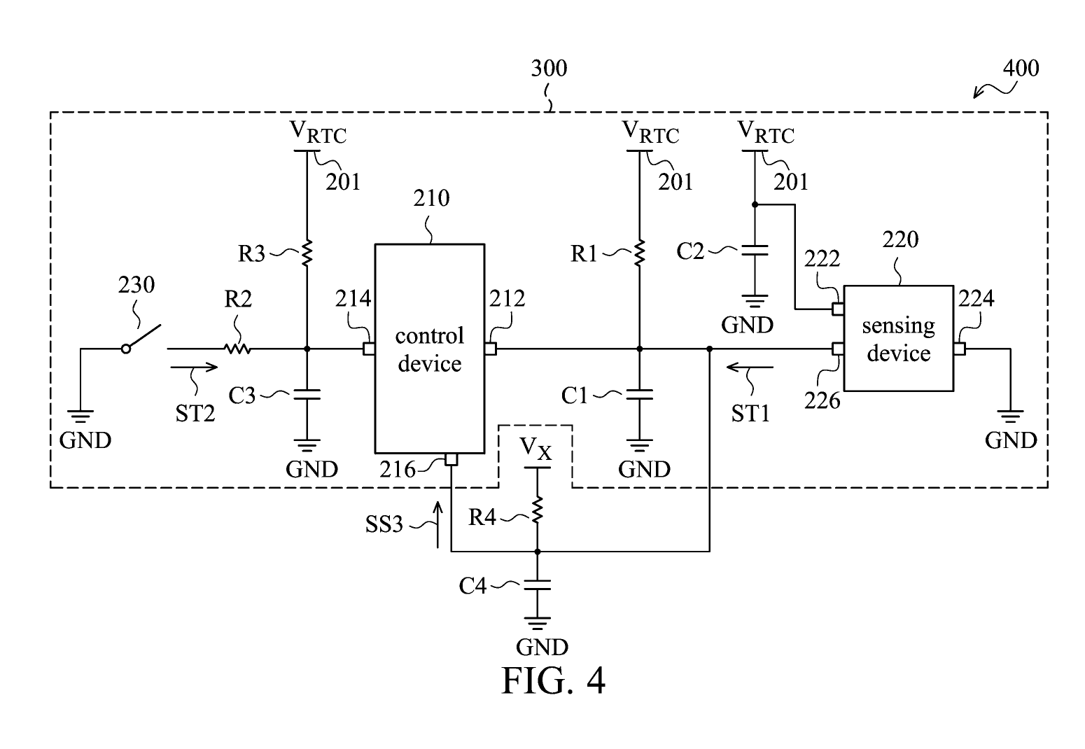

FIG. 4 is a schematic diagram illustrating another embodiment of the switching module of the present disclosure. After the switching module 400 boots the clamshell electronic device 100 according to the trigger signal ST1 or ST2, the switching module 400 can control a backlight module of the clamshell electronic device 100 by the sensing device 220. Compared with the switching module 300 of FIG. 3, the switching module 400 further comprises a resistor R4 and a capacitor C4. For simplification, the connections and operations of other devices of the switching module 400 will not be described in detail here as reference may be made to the description of FIG. 3. The resistor R4 has a first terminal coupled to a pull high voltage V_{X} and a second terminal coupled to the third pin 216 of the control device 210, wherein the resistor R4 pulls high the output voltage at the third pin 226 of the sensing device 220 to a voltage level. The capacitor C4 has a first terminal coupled to the third pin 216 of the control device 210 and a second terminal coupled to the ground GND. The capacitor C4 pre-charges the voltage at the third pin 216 of the control device 210.

In another embodiment, when the clamshell electronic device 100 is under the working state (i.e. the state S0 of the ACPI standard) and the power-saving state (i.e. the states S1 or S2 of the ACPI standard), the third pin 226 of the sensing device 220 and the third pin 216 of the control device 210 is maintained at a high voltage level. When the user closes or opens the upper cap 120 of the clamshell electronic device 100, the sensing device 220 produces a state signal SS3, and sends the state signal SS3 to the third pin 216 of the control device 210. After the control device 210 receives the state signal SS3, the control device 210 turns off or turns on the backlight of the clamshell electronic device 100 according to the state signal SS3, such that the clamshell electronic device 100 enters the power-saving state from the working state or enters the working state from the power-saving state, such as entering into the state S2 from the state S0 or entering into the state S0 from the state S2, though the present disclosure is not limited thereto.

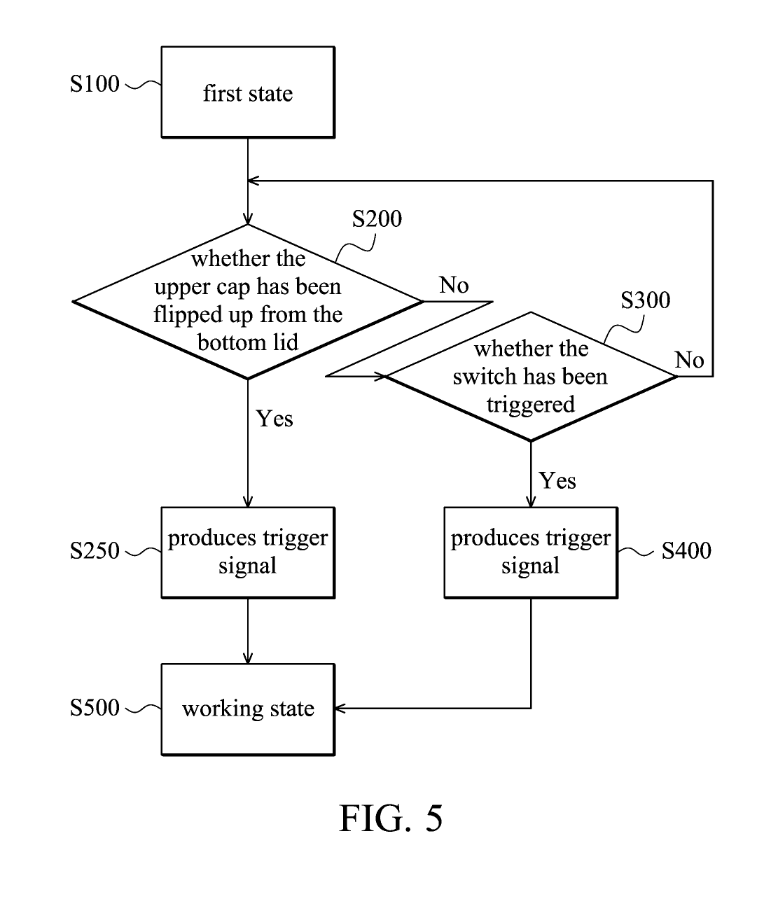

FIG. 5 is a flowchart of an embodiment of a switching method of the present disclosure. In step S100, when the clamshell electronic device 100 is under the first state (i.e. the states S3, S4 or S5 of the ACPI standard), step S200 is performed. In the step S200, the sensing device 224 determines whether the upper cap 120 of the clamshell electronic device 100 has been flipped up from the bottom lid 130 of the clamshell electronic device 100. In the step S200, when the upper cap 120 of the clamshell electronic device 100 has been flipped up from the bottom lid 130 of the clamshell electronic device 100, the sensing device 220 produces a trigger signal ST1 to the control device 210 (step S250), and step S500 is performed. In the step S500, the control device 210 forces the system operating voltage to be provided to the clamshell electronic device 100, such that the clamshell electronic device 100 enters the working state from the first state. When the status of the upper cap 120 and the bottom lid 130 of the clamshell electronic device 100 is not changed (i.e. still closed or opened), step S300 is performed. In the step S300, the sensing device 224 determines whether the switch 230 has been triggered (pressed) by users. When the switch 230 has been triggered (pressed) by users, the switch 230 produces the trigger signal ST2 to the control device 210, as step S400 shows, and the step S500 is performed. In the step S500, the control device 210 forces the system operating voltage to be provided to the clamshell electronic device 100 and the clamshell electronic device 100 enters into the working state from the first state. In the step S300, if the switch 230 has been triggered by users, step S200 is performed. In another embodiment, the switching method further comprises controlling the backlight of the clamshell electronic device 100 according to the state signal SS3 produced by the sensing device 220. For example, when the clamshell electronic device 100 is under the working state or the power-saving state (i.e. the states S0, S1 or S2 of the ACPI), the sensing device 220 produces the state signal SS3 when the user closes or opens the upper cap 120 of the clamshell electronic device 100. After the control device 210 receives the state signal SS3, the control device 210 turns off or turns on the backlight of the clamshell electronic device 100 according to the state signal SS3, such that the clamshell electronic device 100 enters the power-saving state from the working state or enters the working state from a power-saving state.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A clamshell electronic device, comprising:
an upper cap;
a bottom lid;
a first battery, providing a system operating voltage to the clamshell electronic device when the clamshell electronic device is under a working state;
a second battery, providing a booting voltage to the clamshell electronic device when the clamshell electronic device is under a first state;
a sensing device, having a first pin coupled to the booting voltage and a second pin coupled to a ground, wherein a first trigger signal is produced when the upper cap is flipped up form the bottom lid; and
a control device, having a first pin coupled to a third pin of the sensing device, wherein the system operating voltage is forced to be turned on and provided to the clamshell electronic device according to the first trigger signal when the upper cap has been flipped up from the bottom lid, such that the clamshell electronic device enters the working state from the first state.

2. The clamshell electronic device as claimed in claim 1, wherein the working state is state S0 defined by the Advanced Configuration and Power Interface standard, and the first state is a standby state or a shutdown state, and the standby state is state S3 or state S4 defined by the Advanced Configuration and Power Interface standard, and the shutdown state is state S5 defined by the Advanced Configuration and Power Interface.

3. The clamshell electronic device as claimed in claim 1, further comprising:
a first resistor, having a first terminal coupled to the booting voltage, and a second terminal coupled to the first pin of the control device;
a first capacitor, having a first terminal coupled to the first pin of the control device, and a second terminal coupled to the ground; and
a second capacitor, having a first terminal coupled to the first pin of the sensing device and a second terminal coupled to the ground.

4. The clamshell electronic device as claimed in claim 1, further comprising a switch having a first terminal coupled to the ground, and a second terminal coupled to a second pin of the control device to produce a second trigger signal, wherein the control device forces the system operating voltage to be turned on and provided to the clamshell electronic device, such that the clamshell electronic device enters the working state from the first state according to the second trigger signal.

5. The clamshell electronic device as claimed in claim 4, further comprising:
a first resistor, having a first terminal coupled to the second terminal of the switch and a second terminal coupled to the second pin of the control device;
a second resistor, having a first terminal coupled to the booting voltage, and a second terminal coupled to the second terminal of the first resistor; and
a first capacitor, having a first terminal coupled to the second terminal of the first resistor, and a second terminal coupled to the ground.

6. The clamshell electronic device as claimed in claim 1, wherein the control device further comprises a third pin coupled to a third pin of the sensing device to control the backlight of the clamshell electronic device according to a state signal produced by the sensing device during the working state or a power-saving state, and the state signal represents whether the upper cap is flipped up/down.

7. The clamshell electronic device as claimed in claim 6, wherein the power-saving state is state S1 or state S2 defined by the Advanced Configuration and Power Interface standard.

8. The clamshell electronic device as claimed in claim 1, wherein the sensing device is a hall sensor device or a micro-switch.

9. The clamshell electronic device as claimed in claim 1, wherein the second battery is a mercury battery or a capacitor.

10. A switch module, applied to a clamshell electronic device, comprising:
a sensing device, powered by a booting voltage, for detecting whether an upper cap of the clamshell electronic device has been flipped up from a bottom lid of the clamshell electronic device when the clamshell electronic device is under a first state, wherein a first trigger signal is produced when the upper cap has been flipped up from the bottom lid; and
a control device, forcing a system operating voltage to be turned on and provided to the clamshell electronic device according to the first trigger signal, such that the clamshell electronic device enters into a working state from the first state.

11. The switch module as claimed in claim 10, wherein the working state is state S0 defined by the Advanced Configuration and Power Interface standard, and the first state is a standby state or a shutdown state, and the standby state is state S3 or state S4 defined by the Advanced Configuration and Power Interface standard, and the shutdown state is state S5 defined by the Advanced Configuration and Power Interface standard.

12. The switch module as claimed in claim 10, wherein the booting voltage is continually provided by a battery to the clamshell electronic device when the clamshell electronic device is under the first state.

13. The switch module as claimed in claim 10, further comprising a switch coupled to the control device to produce a second trigger signal to the control device, such that the control device forces the system operating voltage to be turned on and provided to the clamshell electronic device, wherein the clamshell electronic device enters the working state from the first state.

14. A switching method, applied to a clamshell electronic device, comprising:
detecting whether an upper cap of the clamshell electronic device has been flipped up from a bottom lid of the clamshell electronic device by a sensing device when the clamshell electronic device is under a first state;
producing a trigger signal when the upper cap of the clamshell electronic device has been flipped up from the bottom lid of the clamshell electronic device; and
forcing a system operating voltage to be turned on and provided to the clamshell electronic device according to the trigger signal, such that the clamshell electronic device enters into a working state from the first state.

15. The switching method as claimed in claim 14, wherein the working state is state S0 defined by the Advanced Configuration and Power Interface standard, and the first state is a standby state or a shutdown state, and the standby state is state S3 or state S4 defined by the Advanced Configuration and Power Interface standard, and the shutdown state is state S5 defined by the Advanced Configuration and Power Interface standard.

16. The switching method as claimed in claim 14, further comprising forcing the system operating voltage to be provided to the clamshell electronic device according to a second trigger signal generated by a switch when the clamshell electronic device is under the first state, such that the clamshell electronic device enters the working state from the first state.

17. The switching method as claimed in claim 14, wherein the sensing device controls backlight of the clamshell electronic device according to a state signal when the clamshell electronic device is under the working state or a power-saving state, and the state signal represents whether the upper cap is flipped up/down.

18. The switching method as claimed in claim 17, wherein the power-saving state is state S1 or state S2 defined by the Advanced Configuration and Power Interface standard.
